(19) United States
(12) Patent Application Publication
(10) Pub. No.: US 2007/0121964 A1
(43) Pub. Date: May 31, 2007

(54) First-order loudspeaker crossover network

(75) Inventor: Mark Francis Rumreich, Indianapolis, IN (US)

Correspondence Address: JOSEPH J. LAKS, VICE PRESIDENT;THOMSON LICENSING LLC, PATENT OPERATIONS, PO BOX 5312, PRINCETON, NJ, 08543-5312, US

(73) Assignee: THOMSON LICENSING INC., Princeton, NJ (US)

(21) Appl. No.: 10/587,188

(22) PCT Filed: Jan. 30, 2004
(86) PCT No.: PCT/US04/02698

§ 371 Date: Jul. 25, 2006

(51) Int. Cl. H03G 5/00

(52) U.S. Cl. 381/99

(57) ABSTRACT

A first-order crossover network having low-pass and high-pass filters to respectively drive first and second loudspeakers in a loudspeaker system is designed such that the phase difference at a crossover frequency between output signals of the first and second loudspeakers is no greater than 60 degrees, so that the output signals are at least partially in phase. Preferably, the phase difference should be about 40 degrees to create a near in-phase effect. The polarity in which the first loudspeaker is coupled to the first-order crossover network is an inverse of the polarity in which the second loudspeaker is coupled to the crossover network. Optionally, the input signals can be equalized to flatten the magnitude responses of the crossover network.

### TECHNICAL FIELD OF INVENTION

This invention relates to the field of loudspeaker crossover networks, and, more particularly, to a first order loudspeaker crossover network having some advantages of a second order loudspeaker crossover network.

### BACKGROUND OF THE INVENTION

A crossover network is used to separate input audio signals into multiple frequency bands in a multi-way loudspeaker system, each band feeding a different loudspeaker best suited for the associated frequency band. A frequency that separates one band from another band is called the crossover frequency of these two bands. For example, in a two-way loudspeaker system to be discussed below, the low frequency and high frequency bands are directed to a woofer and a tweeter, respectively, and the crossover frequency is the frequency where the lower frequency and high frequency bands divide.

In a first-order crossover network, such a first-order Butterworth network, a capacitor is coupled in series to a tweeter, which is essentially resistive, to form a high-pass filter for providing high frequency band signals to the tweeter, and an inductor is coupled in series with a woofer, which is also essentially resistive, to form a low-pass filter for providing low frequency band signals to the woofer. At the crossover frequency, the magnitude response of both low-pass and the high-pass filter is about −3 dB (decibel). Since the phase difference between the two networks is 90 degrees at this crossover frequency, the combined voltage response of this crossover network is 0 dB at the crossover frequency, and no constructive or destructive interference occurs at the crossover frequency.

Although the above first-order crossover network functions satisfactorily, the low-pass and high-pass filters at the crossover frequency are not in-phase. As such, such a first-order network cannot provide the following benefits of an in-phase crossover network: smoother frequency response due to increased stop-band rejection, and improved polar behavior (lobing).

To have an in-phase response, a second-order or higher order crossover network, such as a Linkwitz-Riley network, should be used. However, a second-order or higher order network requires additional capacitors and inductors. For example, a two-way Linkwitz-Riley crossover network requires an additional capacitor coupled in parallel with the woofer to form a low-pass filter, and an additional inductor coupled in parallel with the tweeter to form a high-pass filter. These additional components significantly increase the cost of a loudspeaker system because capacitors and inductors used in a crossover network are generally expensive due to their size, capacity, and power requirements.

### SUMMARY OF THE INVENTION

According to the principles of the invention, a first-order crossover network having low-pass and high-pass filters to respectively drive first and second loudspeakers in a loudspeaker system is designed such that the phase difference at a crossover frequency between responses of the first and second loudspeaker is no greater than 60 degrees, so that the output signals are at least partially in phase. The responses may be electrical or acoustic.

In one embodiment, the low-pass filter is formed by an inductor coupled in series to the first loudspeaker in a first polarity, and the high-pass filter is formed by a capacitor coupled to the second loudspeaker in a second polarity. The impedance of the inductor and the capacitor is selected such that the phase difference is no greater than 60 degrees. Preferably, the phase difference should be about 40 degrees to create a near in-phase effect.

In yet another embodiment, the second polarity is an inverse of the first polarity, for adding a phase shift of 180 degrees to the high-pass filter.

In yet another embodiment, the input audio signals are equalized to flatten the responses of the crossover system. Specifically, the level at the crossover frequency is raised in the input signals.

### BRIEF DESCRIPTION OF DRAWINGS

FIG. 1 is an illustrative two-way loudspeaker system incorporating a crossover network according to the principles of the invention.

FIG. 2 illustrates responses of the woofer in the loudspeaker system as shown in FIG. 1, where the resistance of the woofer is 8 ohms, the capacitor in the high-pass filter has capacitance of 11.5 microfarads, and the inductor in the low-pass filter has inductance of 2.2 millihenrys.

FIG. 3 illustrates responses of the tweeter in the loudspeaker system as shown in FIG. 1, where the resistance of the tweeter is 8 ohms, the capacitor in the high-pass filter has capacitance of 11.5 microfarads, and the inductor in the low-pass filter has inductance of 2.2 millihenrys.

FIG. 4 illustrates combined responses of the loudspeaker system as shown in FIG. 1, where both the woofer and the tweeter have a resistance of 8 ohms, the capacitor in the high-pass filter has capacitance of 11.5 microfarads, and the inductor in the low-pass filter has inductance of 2.2 millihenrys.

FIG. 5 illustrates responses of the woofer in the loudspeaker system as shown in FIG. 1, where the resistance of the woofer is 8 ohms, the capacitor in the high-pass filter has capacitance of 6.7 microfarads, and the inductor in the low-pass filter has inductance of 3.8 millihenrys.

FIG. 6 illustrates responses of the tweeter in the loudspeaker system as shown in FIG. 1, where the resistance of the tweeter is 8 ohms, the capacitor in the high-pass filter has capacitance of 6.7 microfarads, and the inductor in the low-pass filter has inductance of 3.8 millihenrys.

FIG. 7 illustrates combined responses of the loudspeaker system as shown in FIG. 1, where both the woofer and the tweeter have a resistance of 8 ohms, the capacitor in the high-pass filter has capacitance of 6.7 microfarads, and the inductor in the low-pass filter has inductance of 3.8 millihenrys.

FIG. 8 illustrates a response of a equalizer to be used in the loudspeaker system as shown in FIG. 1, where both the woofer and the tweeter have a resistance of 8 ohms, the capacitor in the high-pass filter has capacitance of 6.7 microfarads, and the inductor in the low-pass filter has inductance of 3.8 millihenrys.

FIG. 9 illustrates combined responses of the loudspeaker system as shown in FIG. 1, where both the woofer and the tweeter have a resistance of 8 ohms, the capacitor in the high-pass filter has capacitance of 6.7 microfarads, and the inductor in the low-pass filter has inductance of 3.8 millihenrys, and an equalizer is used to equalize the input audio signals.

FIG. 10 illustrates a method according to the principles of the invention for generating output signals from a loudspeaker system having a first-order crossover network having a phase difference at the crossover frequency of no greater than 60 degrees.

### DETAILED DESCRIPTION

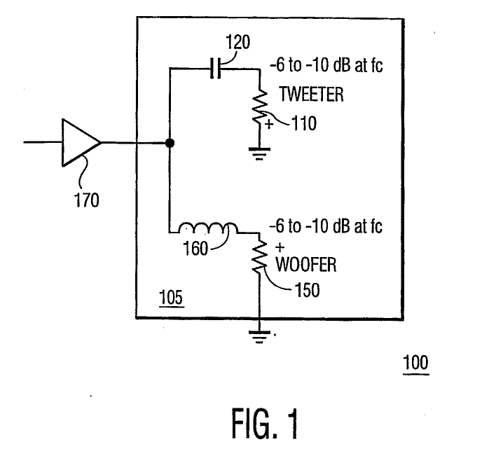

FIG. 1 illustrates a two-way loudspeaker system 100 using a first-order crossover network 105 according to the principles of the invention. The two-way loudspeaker system 100 includes a tweeter 110, represented by a resistor in FIG. 1, and a woofer 150, also represented by a resistor in FIG. 1. Each of the tweeter 110 and the woofer 150 has a positive terminal (shown as + in FIG. 1) and a negative terminal (opposite to the terminal marked as “+” in FIG. 1). Input audio signals to the crossover network 105 may be amplified by an amplifier 170. The crossover network 105 includes a capacitor 120 coupled in series to the tweeter 110 to form a high-pass filter for providing high frequency band input signals to the tweeter 110, and an inductor 160 coupled in series to the woofer 150 to form a low-pass filter for providing low frequency band input signals to the woofer 150. The inductor 160 is coupled to the woofer 150 in a first polarity and the capacitor 120 is coupled to the tweeter 110 in a second polarity, where the second polarity is an inverse of the first polarity. In this example, the inductor 160 is coupled to the positive terminal of the woofer 150, but the capacitor 120 is coupled to the negative terminal of the tweeter 110.

According to the principles of the invention, the capacitance of the capacitor 120 and the inductance of the inductor 160 are selected such that a phase difference at a crossover frequency between the response of the high-pass filter and the response of the low-pass filter is no more than 60 degrees. (A crossover frequency is a frequency where the crossover network 105 divides the audio input signals into high frequency and low frequency bands.) Preferably, the phase difference is about 40 degrees. The inventor recognizes that if the phase difference is no greater than 60 degrees, the responses of the two filters are at least partially in phase. As such, the loudspeaker system produces a smoother frequency response due to increased stop-band rejection, and improved polar behavior. Polar behavior is best understood by looking at the acoustic output plots at the crossover frequency of the combined radiation pattern of the two loudspeakers. A better polar behavior reduces the degradation of audio for off-axis listeners. When the phase difference is at least partially in-phase, the radiation pattern for non-coincident drivers is closer to on-axis for all frequencies, producing at least partial constructive interference and thus improving the polar behavior. For example, if the phase difference is 60 degrees, the two responses produce at least 50% of constructive interference at a crossover frequency. Note that if the phase difference is 180 degrees, the two responses are completely out of phase, producing 100% destructive interference, which, of course, is undesirable. If the phase difference is 90 degrees, such as one produced by a first-order Butterworth filter, the two responses are in quadrature, producing neither constructive nor destructive interference. If the phase difference is zero, such as one produced by the second-order Linkwitz-Rilley filter, the two responses are completely in phase, producing 100% constructive interference. The first-order crossover network 105 according to the principles of the invention produces a phase difference much closer to zero degree than a conventional first-order crossover network.

In the following illustration of first and second examples, it is assumed that the internal resistance of the tweeter 110 and the woofer 150 is 8 ohms and the crossover frequency is 1000 Hz (hertz). Since the impedances of the tweeter 110 and the woofer 150 are treated as pure resistive, the acoustic response of each of the tweeter 110 and the woofer 150 is the same as its electrical response. The acoustic response of a loudspeaker is the response in term of the acoustic output of the loudspeaker, and the electrical response is the response in term of the voltage developed across the two terminals of the loudspeaker. In the real world, a loudspeaker is not purely but is substantially resistive. Thus, the electrical response of a loudspeaker is substantially the same as the acoustic response.

In the first example, the crossover network 105 produces a phase difference of about 60 degrees at the crossover frequency. An example for producing such as a phase difference is to select a capacitance of 1.5 uF (microfarads) for the capacitor 120 and an inductance of 2.2 mH (millihenrys) for the inductor 160. With this set of values, the low pass filter produces a positive phase shift of about 60 degrees and the high-pass filter produces a negative phase shift of about 60 degrees. However, since the low-pass filter is connected to the positive terminal of the woofer 150 but the high-pass filter is connected to the negative terminal of the tweeter 110, i.e., the polarity of the tweeter 110 is inverted with respect to the woofer 160, the tweeter 110 actually adds a positive phase shift of 180 degrees to the high-pass filter. The reason that inverting the polarity adds 180 degrees to the high-pass filter is that the incoming signals are essentially reversed. For example, a positive input would become negative, moving a cone of the tweeter 110 in an opposite direction. Thus, the resulting phase shift for the high-pass filter is actually a positive phase shift of about 120 degrees. Thus, the phase difference between the response of the low-pass filter and the response of high-pass filter is about 60 degrees.

In the second example, the crossover network 105 produces a phase difference of about 40 degrees. An example for producing such as a phase difference is to select a capacitance of 6.7 uF for the capacitor 120 and an inductance of 3.8 mH for the inductor 160. With this set of values, the low pass filter produces a positive phase shift of about 71 degrees and the high-pass filter produces a negative phase angle of about 71 degrees. However, the tweeter 110 adds a positive phase shift of 180 degrees to the high-pass filter because of the reverse polarity. Thus, the resulting phase shift for the high-pass filter is actually a positive phase shift of 109 degrees. Thus, the phase difference between the response of the low-pass filter and the response of high-pass filter is about 38 degrees.

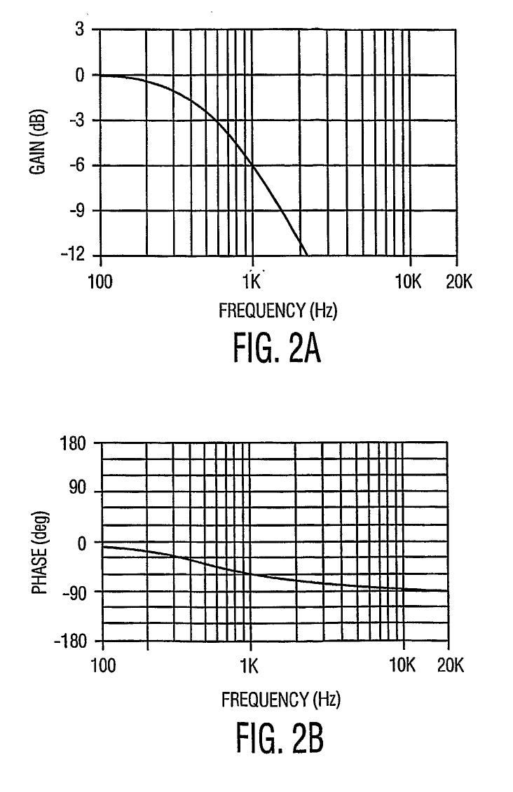

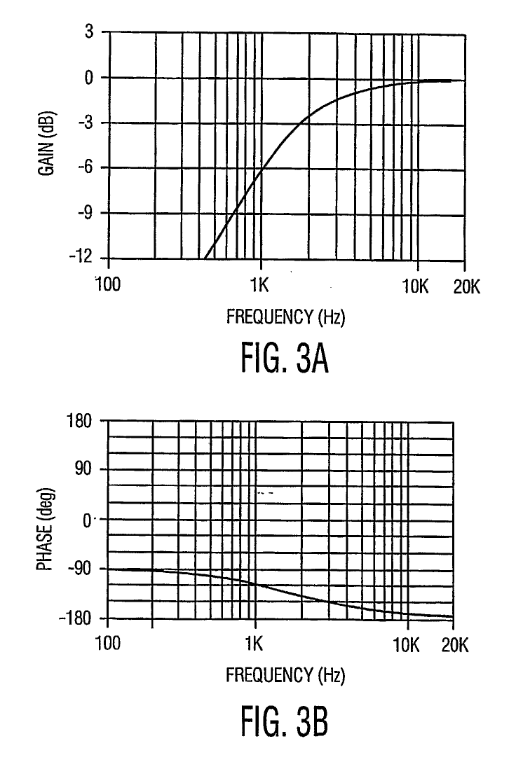

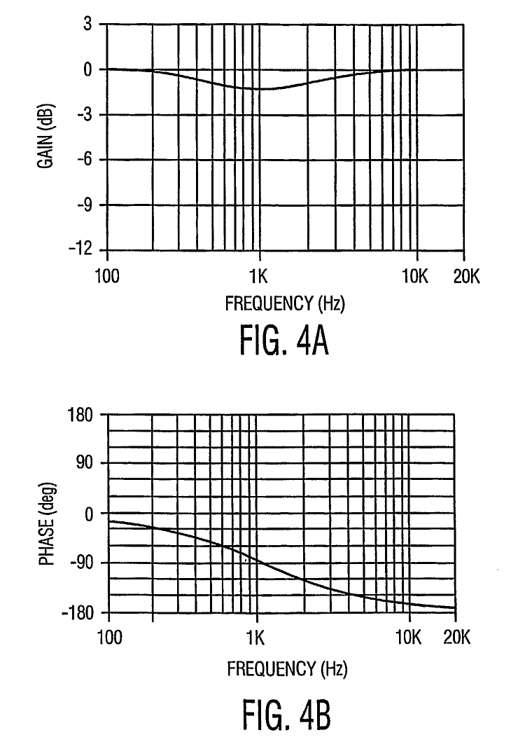

FIGS. 2, 3, and 4 show the magnitude and phase responses of the crossover network 105 in the first example. FIG. 2 shows the responses for the low-pass filter, FIG. 3 shows the responses for the high-pass filter, and FIG. 4, shows the combined responses. The passbands, shown in FIGS. 2 and 3, are narrower than a traditional first-order crossover networks having a phase difference of 90 degrees. Each of the high-pass and low-pass filters has a magnitude response of about −6 dB at the crossover frequency and the combine magnitude is about −1 dB.

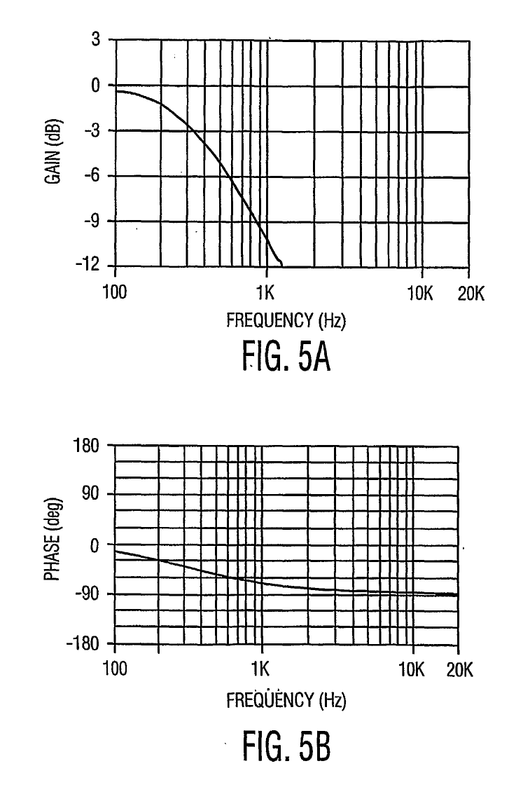

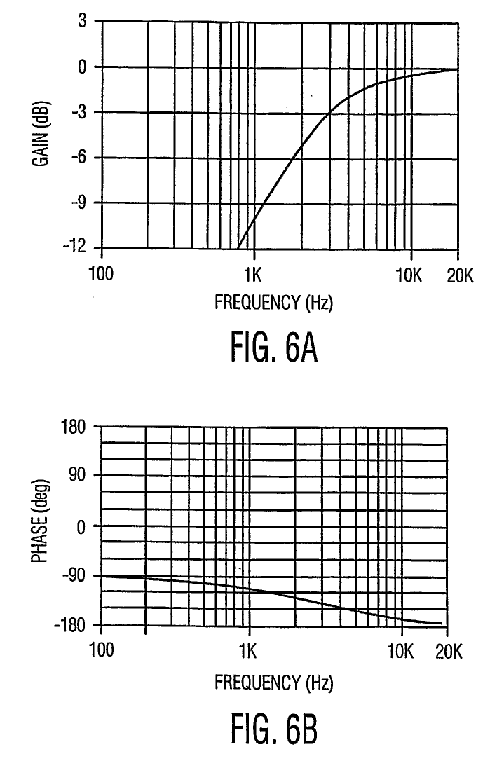

FIGS. 5, 6, and 7 respectively show the magnitude and phase responses of the low-pass filter, the high-pass filter, and the combined responses of the crossover network 105 in the second example. As can be seen from FIGS. 5 and 6, the passbands are narrower than those in the first example. Each of the high-pass and low-pass filters has a magnitude response of about −10 dB at the crossover frequency and the combined magnitude is about −4.5 dB.

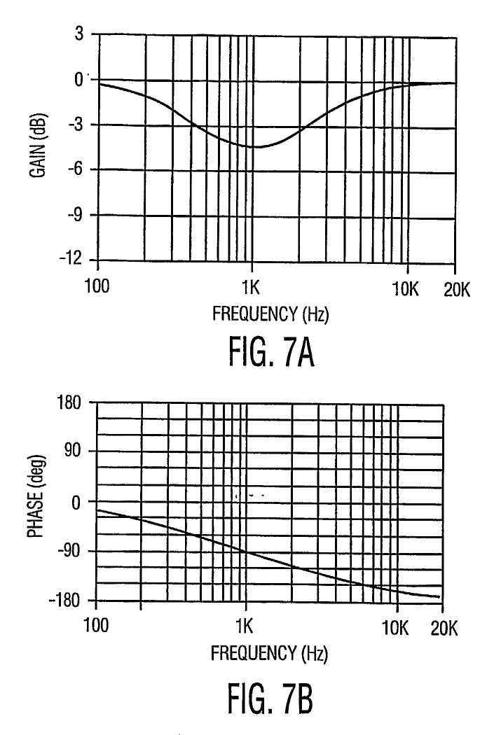

It is observed that in order to achieve the at least partially in-phase first order network 105, the individual responses for the high-pass and low-pass filters should be about −6 dB or less. For example, the individual responses for the crossover network 105 in the first and second examples are about −6 dB and −10 dB, respectively. The midrange dips shown in FIGS. 4 and 7 can be improved, if necessary, by using an equalizer (not shown) to equalize the input signals before the input signals enter the crossover network 105. The input signals are equalized preferably before they are amplified by the amplifier 170.

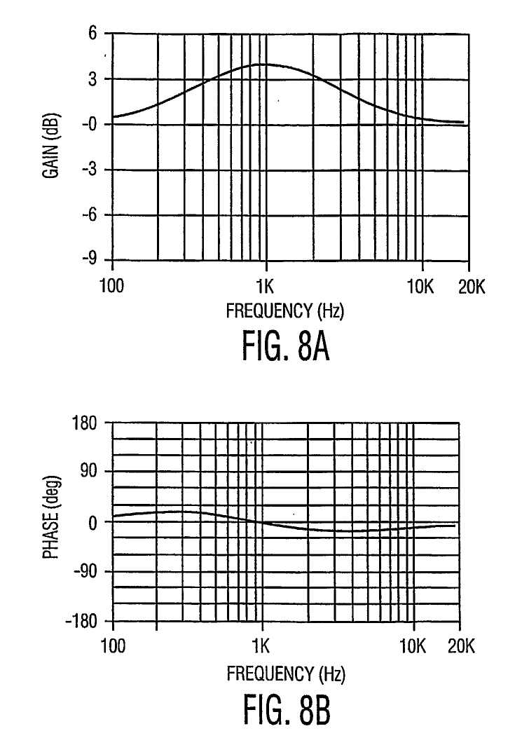

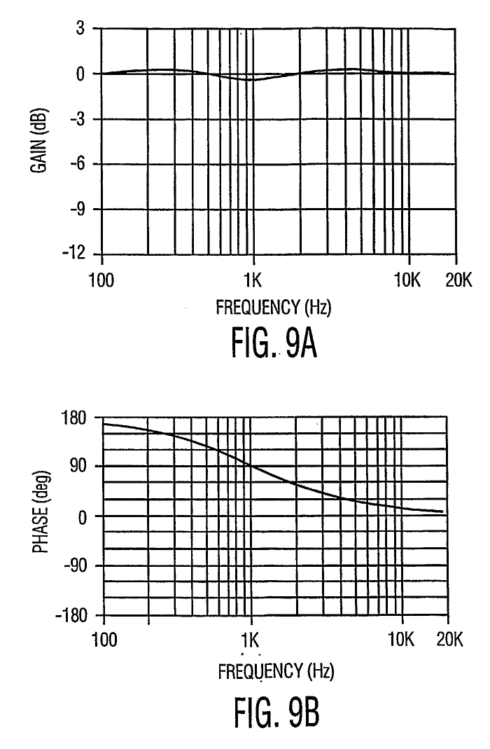

For example, if an equalizer having responses shown in FIG. 8 is used to equalize the input signals before the input signals enter the crossover network 105 in the second example, the combined response is almost flat as shown in FIG. 9.

Although illustrated as having the crossover frequency of 1,000 Hz, other crossover frequency, such as 1,700 Hz, can be used. Furthermore, although the internal resistances of the tweeter 110 and the woofer 150 are illustrated as 8 ohms, other resistances, such as 6 ohms, can be used, and the internal resistance of the tweeter 110 can be different from that of the woofer 150. Furthermore, although illustrated that the low-pass and high-pass filters produce the same amount of phase shift but in different direction, the absolute amounts of the two phase shifts may differ from each other. Lastly, although illustrated as used in a two-way loudspeaker system, the principles of the invention can be applied to a three-way or other multi-way loudspeaker system. For example, the principles of the invention can be applied to the design of the low-pass filter and the band-pass filter, and the design of the band-pass filter and the high-pass filter in a three-way loudspeaker system.

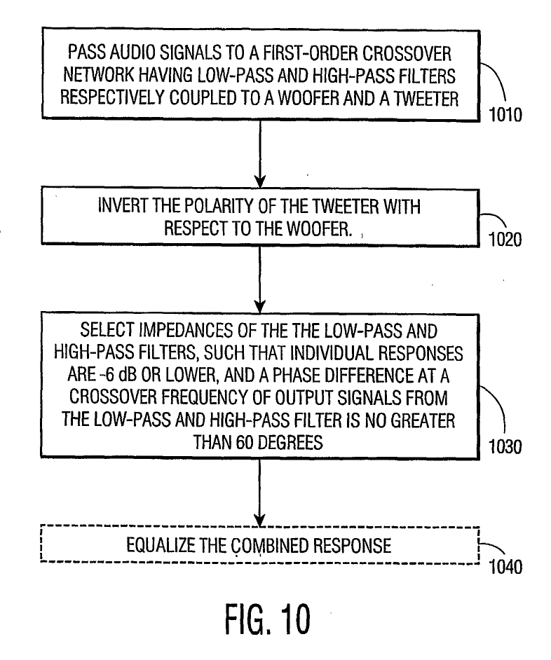

FIG. 10 illustrates a method according to the principles of the invention for generating output signals from a loudspeaker system having a first-order crossover network having a phase difference at the crossover frequency of no greater than 60 degrees. At step 1010, audio signals are passed to a first-order passive crossover network having low-pass and high-pass filters respectively coupled to a woofer and a tweeter. At step 1020, the polarity of the tweeter with respect to the woofer is inverted. At step 1030, impedances of the low-pass and high-pass filters are selected such that individual responses of the two filters are −6 dB or lower, preferably between −6 dB and −10 dB at the crossover frequency, and a phase difference at the crossover frequency between respective output signals from the low-pass and high-pass filters is no greater than 60 degrees. This will produce a low-pass phase shift of 60 degrees or higher, and a high-pass phase shift of −60 degrees or lower. With the inverting polarity, the tweeter adds a phase shift of +180 degrees to the high-pass filter, resulting in an equivalent high-pass shift of +120 degrees or less. Thus, the phase difference between the low-pass and the high-pass filters is 60 degrees or less, or at least partially in phase at the crossover frequency. Optionally, at step 1040, the combined response is obtained and the input signals are equalized to compensate the dips in the area near the crossover frequency.

While this invention has been described with regard to a few presently preferred embodiments, those skilled in this art will readily appreciate that many alternative modes and embodiments can be carried out without departing from the spirit and scope of this invention.

1. A first-order crossover network for dividing input audio signals into high and low frequency bands at a crossover frequency in a loudspeaker system having first and second loudspeakers having respective impedance, each loudspeaker having positive and negative terminals, the first-order crossover network comprising:
a first component coupled to the first loudspeaker to form a low-pass filter for providing the first loudspeaker low frequency band signals; and
a second component coupled to the second loudspeaker to form a high-pass filter for providing the second loudspeaker high frequency band signals, wherein the low-pass and the high-pass filters are first-order filters, and impedances of the first and second components are selected such that a phase difference at the crossover frequency between respective responses of the first and second loudspeakers is no greater than 60 degrees.

2. The crossover network of claim 1, wherein the responses are acoustic responses.

3. The crossover network of claim 1, wherein the responses are electrical responses.

4. The crossover network of claim 1, wherein the first component is coupled in series to the first loudspeaker in a first polarity, the second component is coupled in series to the second loudspeaker in a second polarity, and the second polarity is an inverse of the first priority.

5. The crossover network of claim 4, wherein the first component is an inductor, the second component is a capacitor, and impedance of the inductor and the capacitor is selected such that the phase shift for each filter is no less than 60 degrees.

6. The crossover network of claim 5, wherein the input audio signals are equalized to flatten combined response of the first and second loudspeakers.

7. The crossover network of claim 6, wherein the combined response at the crossover frequency is raised.

8. The crossover network of claim 7, wherein the combined response at the crossover frequency is raised by about 4.5 decibels.

9. The crossover network of claim 1, wherein combined response of the first and second loudspeakers is no greater than −6 decibels.

10. The crossover network of claim 9, wherein the combined response is no less than −10 decibels.

11. The crossover network of claim 1, wherein the phase difference is about 40 degrees.

12. A loudspeaker system comprising:
first and second loudspeakers having respective impedance, each loudspeaker having positive and negative terminals; and
a crossover network, being a first-order network, for dividing input audio signals into high and low frequency bands at a crossover frequency, the crossover network including first and second components respectively coupled to the first and second loudspeakers to form respective low-pass and high-pass filters for providing the low and high frequency band signals to the respective first and second loudspeakers, wherein the low-pass and high-pass filters are first-order filters, and the impedance of the first and second components is selected, such that a phase difference between respective responses of the first and second loudspeakers is no greater than 60 degrees at the crossover frequency.

13. The loudspeaker system of claim 12, wherein the responses are acoustic.

14. The loudspeaker system of claim 13, wherein the responses are electrical.

15. The loudspeaker system of claim 14, wherein the first component is coupled in series to the first loudspeaker in a first polarity, the second component is coupled in series to the second loudspeaker in a second polarity, and the second polarity is an inverse of the first priority.

16. The loudspeaker system of claim 15, wherein the first component is an inductor, the second component is a capacitor, and impedance of the inductor and the capacitor is selected such that the phase shift for each filter is no less than 60 degrees.

17. The loudspeaker system of claim 16, further comprising an equalizer for equalizing the input audio signals to flatten combined response of the first and second loudspeakers.

18. The loudspeaker system of claim 17, wherein the combined response at the crossover frequency is raised.

19. The loudspeaker system of claim 18, wherein the combined response at the crossover frequency is raised by 4.5 decibels.

20. The loudspeaker system of claim 14, wherein combined response of the first and second loudspeakers is no greater than −6 decibels.

21. The loudspeaker system of claim 20, wherein the combined response is no less than −10 decibels.

22. A method for generating output signals from a loudspeaker system having first and second loudspeakers, the method comprising the steps of:
passing audio signals to a first-order crossover network including low-pass and high-pass filters;
coupling the low-pass filter to the first loudspeaker in a first polarity, and coupling the high-pass filter to the second loudspeaker in a second polarity, wherein the second polarity is an inverse of the first polarity; and
selecting impedances of the first and second filters, such that each filter has a frequency response of no greater than −6 decibels at a crossover frequency, and a phase difference at a crossover frequency of output signals of the low-pass and high-pass filters is no greater than 60 degrees.

23. The method of claim 22, further comprising the step of equalizing input signals to equalize responses of the loudspeaker system.

24. The method of claim 23, wherein the phase difference is about 40 degrees.

25. The method of claim 23, wherein impedance of the first loudspeaker is the same as impedance of the second loudspeaker.

26. The method of claim 23, wherein the impedance of the first and second loudspeakers is different.
